(19) United States
(12) Patent Application Publication
(10) Pub. No.: US 2018/0327897 A1
(43) Pub. Date: Nov. 15, 2018

(54) RE-DEPOSITION FREE SPUTTERING SYSTEM

(71) Applicant: Applied Materials, Inc., Santa Clara, CA (US)

(72) Inventor: Aki HOSOKAWA, Sunnyvale, CA (US)

(21) Appl. No.: 15/961,607

(22) Filed: Apr. 24, 2018

Related U.S. Application Data
(60) Provisional application No. 62/505,694, filed on May 12, 2017.

(51) Int. Cl. C23C 14/35

(52) U.S. Cl. CPC C23C 14/35

(57) ABSTRACT

A cylindrical target assembly for use in a physical vapor deposition (PVD) processing chamber for magnetically enhanced sputtering applications. In embodiments disclosed herein, a cylindrical target, disposed around a rotatable backing tube, has one or more contoured ends that conform to a magnetic sputtering line located outside of a uniform magnetic field. The contoured ends prevent or substantially reduce the accumulation of redeposition material at either end of the cylindrical target assembly desirably reducing particle contamination in the process chamber and on the surfaces of substrates processed therein.

### CROSS-REFERENCE TO RELATED APPLICATIONS

This application claims priority to U.S. Provisional Application Ser. No. 62/505,694, filed on May 12, 2017, which is herein incorporated by reference in its entirety.

### BACKGROUND

### Field

Embodiments of the present disclosure generally relate to physical vapor deposition (PVD) of thin films, and more particularly, to sputtering using a cylindrical rotary target.

### Description of the Related Art

In many applications it is desirable to deposit thin layers of material onto a substrate. Known techniques for depositing thin layers are, in particular, chemical vapor deposition (CVD) and physical vapor deposition (PVD), which includes evaporation and sputtering. Sputtering applications include the manufacturing of flat panel displays (FPDs) based on thin film transistors (TFTs). FPDs are typically manufactured on thin rectangular sheets of glass or polymer. The electronic circuitry formed on the glass panel is used to drive optical circuitry, such as liquid crystal displays (LCDs), organic LEDs (OLEDs) or plasma displays subsequently mounted on or formed in the glass pane. Other types of flat panel displays are based on organic light emitting diodes (OLEDs).

One type of sputtering process is magnetically enhanced sputtering using a rotatable sputtering cathode. During a typical sputtering process, a target of desired target materials is bombarded with atoms, molecules, or ions generated from a sputtering gas that have sufficient energy to dislodge particles of target material from the target surface. The sputtered particles are deposited onto a substrate that is often grounded to function as an anode. During a magnetically enhanced sputtering process, a magnetron with an array of magnets is mounted in a fixed position behind a target to a magnetic field near the surface of the target. The magnetic field defines a sputtering region where ions formed from the sputtering gas are concentrated and move with high velocity towards, and substantially perpendicular to, the target surface. The ions dislodge particles from the target surface which are then deposited on a substrate surface opposite the sputtering region of the target. The increased energy of ions from magnetically enhanced sputtering results in desirably increased deposition rates. However, uneven bombardment of the target surface due to the shape of the magnetic field results in undesirable erosion patterns. Rotating targets, in particular cylindrical rotating targets reduce uneven erosion patterns. A rotatable cylindrical target assembly generally includes a cylindrical tube, or backing tube, having a layer of target material disposed thereon. The backing tube, and the target material disposed thereon, rotates over the fixed magnet array which results in a more uniform erosion pattern along the majority of the length of the cylinder. However, a non-uniform and weaker magnetic field at the ends of the cylindrical target results in decreased erosion and, in some cases, a build-up of redeposited target material on the target surface. This redeposited material forms weakly adhered layers that are prone to flaking off, causing particle problems in the process chamber and on the substrate surface.

Accordingly, there is a need in the art for a rotatable target that eliminates or substantially reduces the build-up of redeposited target material on the target surface.

### SUMMARY

Embodiments of the present disclosure generally comprise a rotatable cylindrical target for use in magnetically enhanced sputtering chamber. The cylindrical target has one or more contoured surfaces at the respective ends thereof where the contoured surfaces conform to a magnetic field provided by a stationary magnet array. The contoured surfaces prevent the accumulation of previously sputtered material (redeposition) at the end of the cylindrical target by ensuring that all surfaces of the cylindrical target are within a region of the magnetic field that has sufficient strength to redirect previously sputtered material away from the surface of the cylindrical target. In one embodiment the contoured surface has an arc shape joining an outer and an inner surface of the cylindrical target. In another embodiment, the contoured end comprises a chamfer. In some embodiments, the cylindrical target assembly further comprises a dark space shield spaced apart from the cylindrical target. In some embodiments, the dark space shield has a contoured portion to ensure that a gap between the cylindrical target and the dark space shield does not exceed a dark space length which prevents any undesirable plasma from forming in the gap.

In one embodiment, a cylindrical target assembly includes a backing tube and a cylindrical target disposed about the backing tube. The cylindrical target features an inner surface, an outer surface coaxially disposed about the inner surface, and one or more contoured surfaces each extending from the inner surface to the outer surface at a respective target end.

In another embodiment, a cylindrical target assembly includes a backing tube, a cylindrical target disposed about the backing tube, and one or more shields disposed about, and spaced apart from, the backing tube. The cylindrical target features an inner surface, an outer surface coaxially disposed about the inner surface, and one or more contoured surfaces each extending from the inner surface to the outer surface at a respective target end.

In another embodiment, a cylindrical target assembly includes a backing tube and a cylindrical target disposed around the backing tube. The cylindrical target features an inner surface having an inner diameter, an outer surface having an outer diameter, and a contoured surface extending from the inner surface to the outer surface at an end of the cylindrical target, wherein the contoured surface joins the outer surface between about 5 mm and about 20 mm from the end of the cylindrical target when measured parallel to the longitudinal axis thereof.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a deposition apparatus having cylindrical target assemblies and cylindrical targets, according to embodiments described herein.

FIG. 2A is a cross sectional side view of an end portion of a cylindrical target assembly, according to the prior art.

FIG. 2B is a cross sectional front view of the end portion of the cylindrical target assembly of FIG. 2A.

FIG. 2C is a close up view of the cylindrical target and dark space shield shown in FIGS. 2A-2B.

FIG. 2D is a close up view of an erosion profile of the cylindrical target of FIGS. 2A-2C.

FIG. 3A is a cross sectional side view of an end portion of a cylindrical target assembly, according to one embodiment.

FIG. 3B is a close up view of the cylindrical target and dark space shield shown in FIG. 3A.

FIG. 3C is a close up view of an erosion profile of the cylindrical target of FIGS. 3A-3B.

FIG. 4 is a close up view of a cylindrical target and dark space shield, according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally comprise a cylindrical target assembly, including a cylindrical target and a dark space shield, for use in magnetically enhanced sputtering applications to substantially reduce or eliminate accumulation of redeposition material on surfaces of a cylindrical target.

Re-deposition is the deposition of previously sputtered material (atoms or molecules) onto the surface of a target that the material was originally sputtered from. Generally, re-deposition occurs when material that has been sputtered from the target surface collides with other sputtered material or atoms, molecules, or ions and bounces back towards the target surface. If the sputtering energy at the target surface is strong enough, the previously sputtered material will be redirected from the target or will be immediately resputtered after re-depositing on the target surface. If the sputtering energy at the target surface is weak, the particle will tend to adhere to the target surface and form a layer of redeposited material. Typically, the layer of redeposited material has a powder like consistency and will easily flake from the target surface which causes particle contamination issues on the substrate.

Generally, sputtering energy at the target surface is localized to a sputtering region between the ends of the target due to the use of an array of magnets disposed within the cylindrical target assembly. The magnetic field provided by the array of magnets concentrates a plasma, typically formed using an inert gas, such as argon, within the magnetic field. The magnetic field is substantially uniform along a majority of the length of the sputtering region, however, the magnetic field will necessarily dissipate at either end of the cylindrical target assembly which reduces the concentration of ions at the end regions of the cylindrical target. Embodiments herein disclose a cylindrical target where the target ends are contoured to conform to the shape of the magnetic field at either end of the cylindrical target.

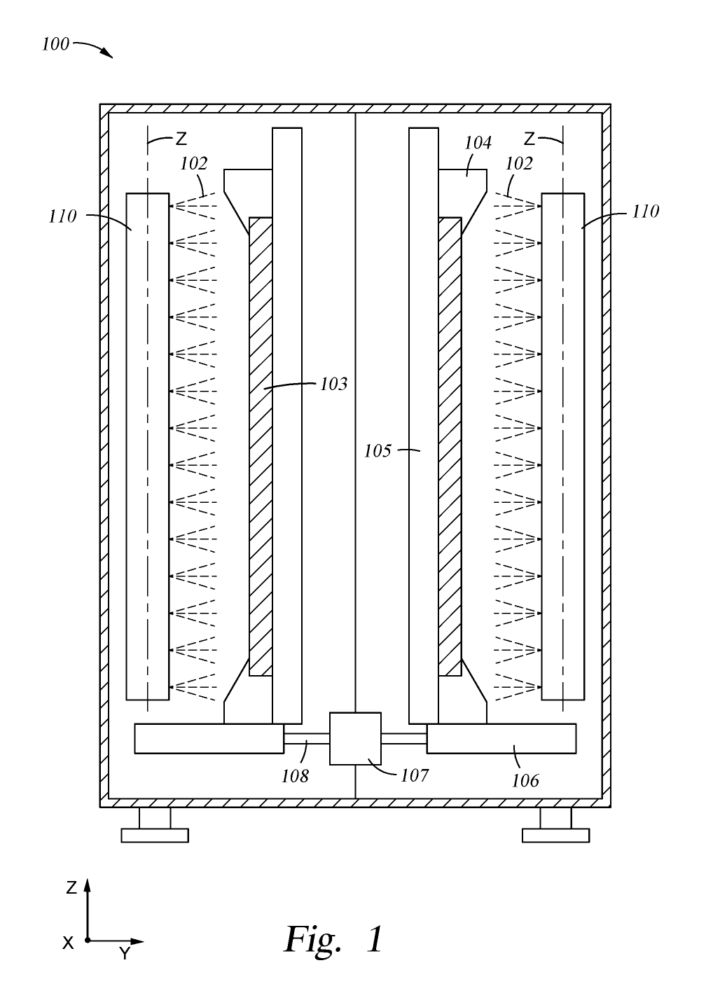

Herein, the target material of the cylindrical target is chosen according to the deposition process and the later application of the coated substrate. For example, the target material may be selected from the group consisting of a metal or a dielectric material, such as aluminum, molybdenum, titanium, copper, or the like, silicon, IZO, IGZO, AZO, SnO, AlSnO, InGaSnO, ceramics, and other materials, such as materials used to form a transparent conductive oxide. Typically, oxide-, nitride- or carbide-layers, which can include such materials, can be deposited by providing the material from the source or by reactive deposition, i.e. the material from the source reacts with elements like oxygen, nitride, or carbon from a processing gas provided to the process chamber. Embodiments of the cylindrical target assembly disclosed herein may be used in a sputtering process chamber, such as the process chamber 100 shown in FIG. 1.

FIG. 1 shows a schematic view of a process chamber 100 where one or more substrates 103 are mounted in one or more substrate carriers 104 that support the substrates 103 in substantially vertical positions. The substrate carriers 104, and thus the substrates 103, are transported by a transport system which includes a plurality of upper rollers 105 for supporting the substrate carrier 104 in the vertical position and a plurality of lower rollers 106 for moving the substrate 103 into and out of the process chamber 100. The plurality of lower rollers 106 are rotated by a rotary shaft 108 coupled to a motor 107. The substrate surface, which is to be coated, faces the cylindrical target assembly 110 and a target material 102 is sputtered from the cylindrical target assembly 110 onto the surface of the substrate 103.

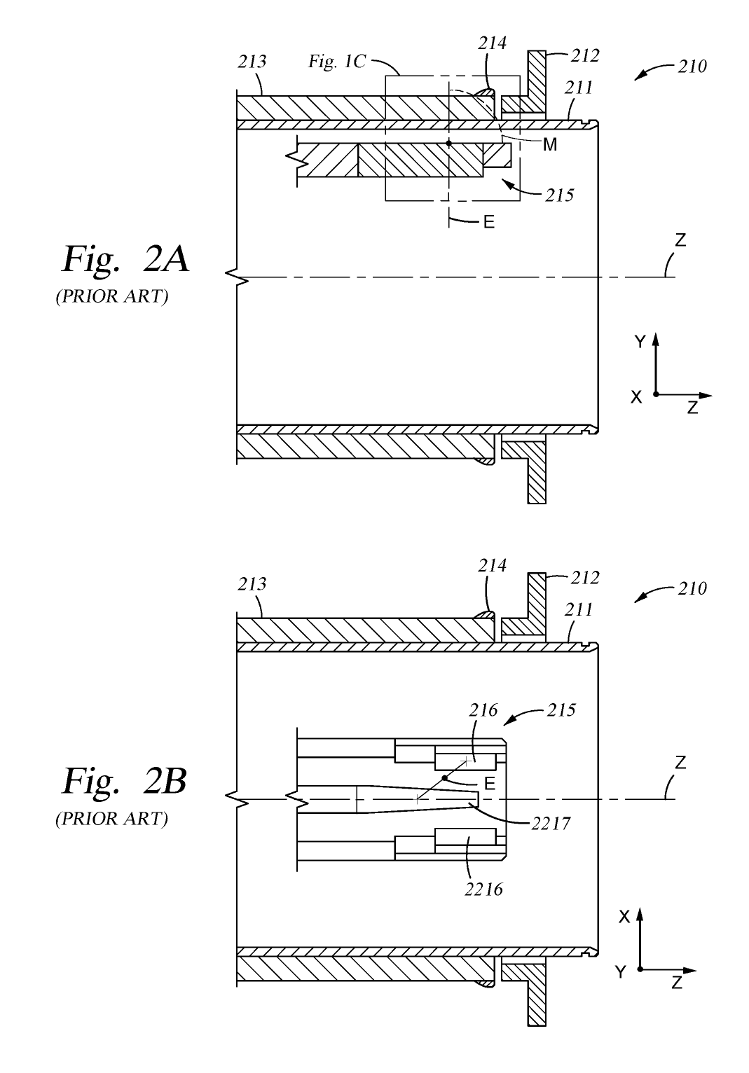

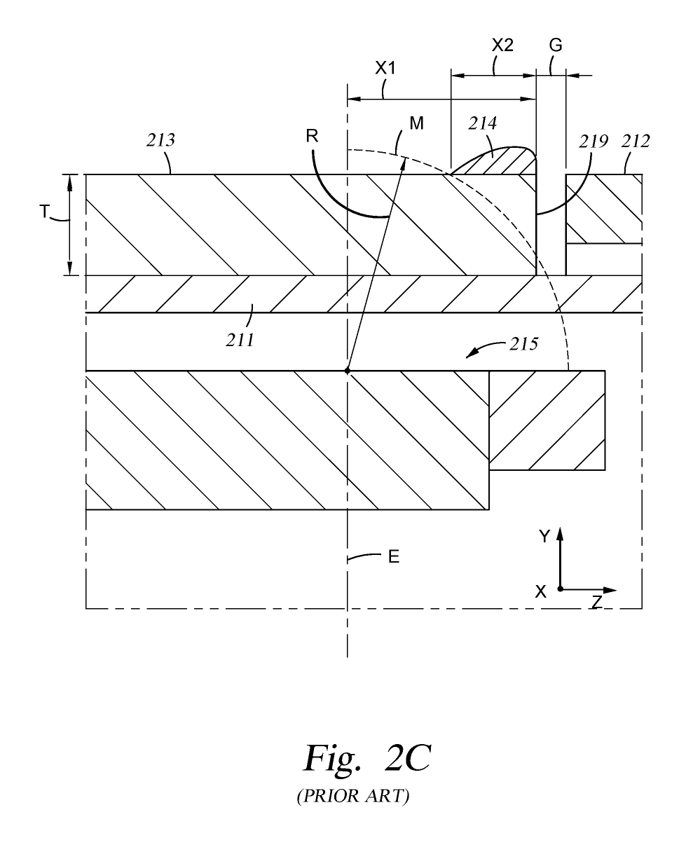

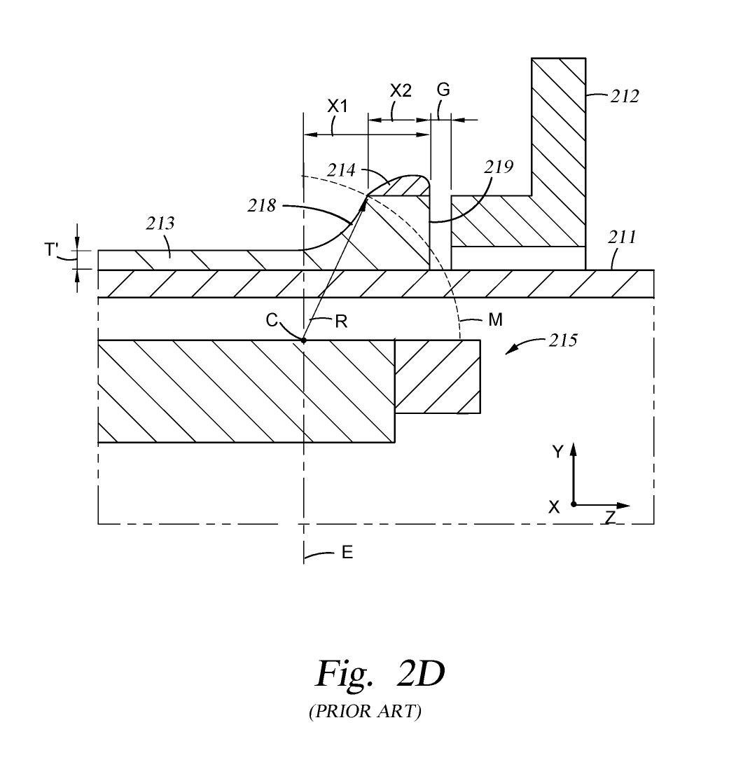

FIGS. 2A and 2B show an end of a conventional cylindrical target assembly 210, according to the prior art, that is used in the process chamber 100 as the cylindrical target assembly 110. Another end, not shown, of the cylindrical target assembly 210, is a mirror image of FIGS. 2A and 2B, however, the polarity of the magnets are reversed. The cylindrical target assembly 210 includes a backing tube 211 having a cylindrical target 213 disposed thereon, and a magnet array assembly 215 comprising a plurality of magnets of alternating polarity disposed therein. The cylindrical target assembly 210 further includes a dark space shield 212 disposed around an end of the backing tube 211, where the dark space shield 212 is spaced apart from both the cylindrical target 213 and the backing tube 211. The dark space shield 212, electrically isolated from the backing tube 211, protects the backing tube 211 from ion bombardment. The backing tube 211, and the cylindrical target 213 disposed thereon, rotate about a longitudinal axis Z of the cylindrical target 213 while the magnet array assembly 215 remains stationary. FIG. 2A shows a profile view, and FIG. 2B shows a front view, of the magnet array assembly 215 as disposed in the backing tube 211.

The magnet array assembly 215 includes a plurality of magnets of alternating polarity that provide a substantially uniform magnetic field between two uniform magnetic field edges E. The uniform magnetic field edges E are perpendicular to an outward facing surface of the center end magnet 217. The uniform magnetic field edges E are located at each end of the cylindrical target assembly 210 and are found by bisecting a straight line drawn from the center of an outside pole of outside end magnet 216 to the center of an outside pole of a center end magnet 217. At each end of the cylindrical target assembly 210, the magnetic field gradually weakens radially outward from the intersection of the uniform magnetic field edge E and the surface of the center end magnet 217, which is the area to the right of the uniform magnetic field edge E in FIGS. 2A-2D.

FIG. 2C is a close up view of a portion of the end of the cylindrical target assembly 210, as shown in FIG. 2A and according to the prior art. FIG. 2C shows the magnetic field edge E, and the outer surface of the cylindrical target 213 extending beyond the uniform magnetic field edge E by a first distance X1, where first distance X1 is between about 20 mm and about 40 mm. The second distance X2 is defined by both a region of little to no sputtering and a region of accumulated redeposition material 214, as they are typically related. Generally, little to no sputtering takes place on the surface of the cylindrical target 213 along second distance X2 due to the weak magnetic field found at the surface outside of an equal magnetic line M, where outside refers to the area between equal magnetic line M and the end of the target, or to the right of the equal magnetic line M in FIGS. 2A-2D. During processing, redeposition material 214 accumulates on the surface of the cylindrical target 213 in this same area, which is between a target end 219 and equal magnetic line M, or along the second distance X2, where the second distance X2 is between about 5 mm and about 20 mm, such as between about 10 mm and about 15 mm, such as about 10 mm. Herein, the equal magnetic line M has a radius R, where radius R is the distance from the uniform magnetic field edge E, at an outward facing surface of center end magnet 217, and the second distance X2 from target end 219 at the surface of the cylindrical target 213 having a thickness T. Because FIG. 2C further discloses a gap G disposed between the target end 219 and the dark space shield 212. The gap G is less than about one dark space length, where one dark space length is the distance that an electron must travel under an applied potential and gas pressure before acquiring enough energy to initiate ionization of the sputtering gas and form a plasma therefrom. The gap G is typically about 3 mm for most sputtering processes.

FIG. 2D shows an erosion profile of a used target surface, according to the prior art. Typically, the surface of the cylindrical target 213 erodes at a uniform rate between the uniform magnetic field edge E and an opposing uniform magnetic field edge at the opposite end of the cylindrical target assembly, not shown. The uniform erosion of the surface of the cylindrical target 213 results in a used thickness T′ along the majority of that surface. Between the uniform magnetic field edge E and a target end 219 the magnetic field dissipates until no or little erosion takes place, which causes the redeposition material 214 to accumulate on the surface of the cylindrical target 213. As shown, the accumulation of redeposition material 214 along second distance X2 substantially corresponds to an area of little or no target erosion. End profile 218 shows a typical non-uniform erosion profile between the uniform magnetic field edge E and equal magnetic line M.

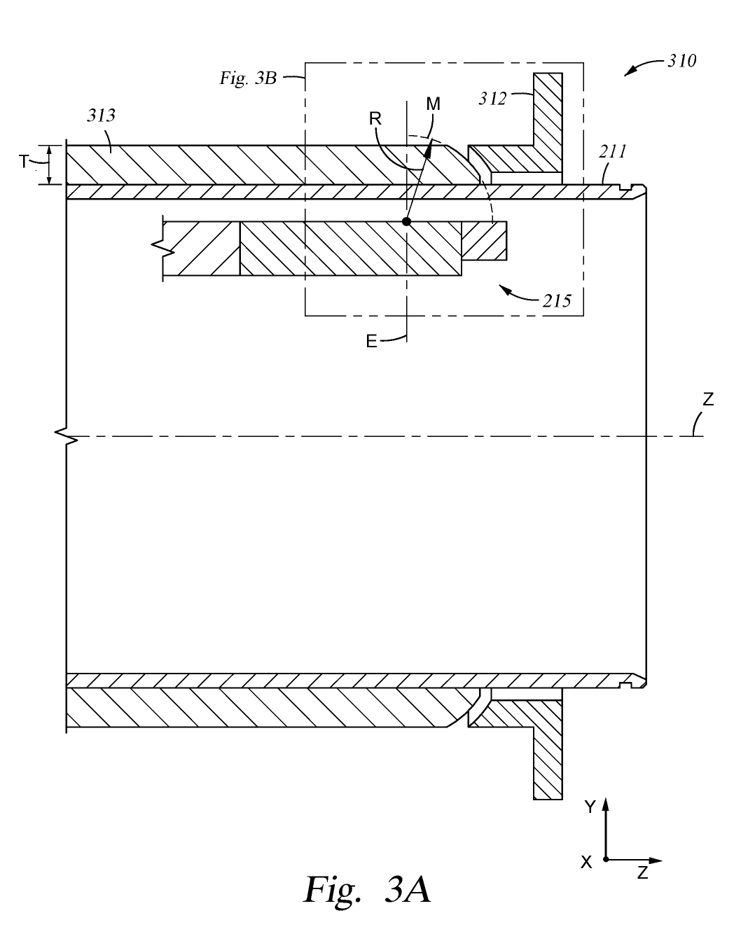

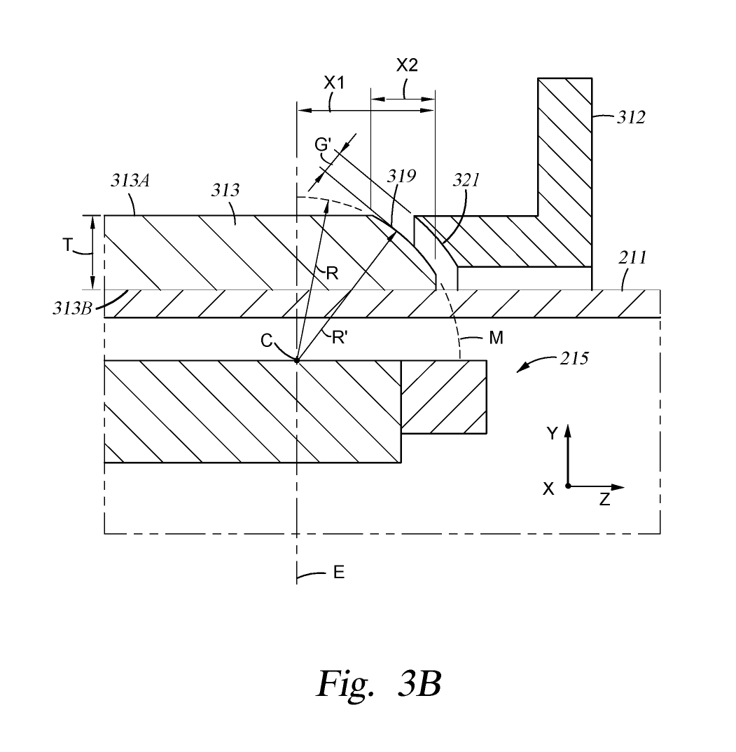

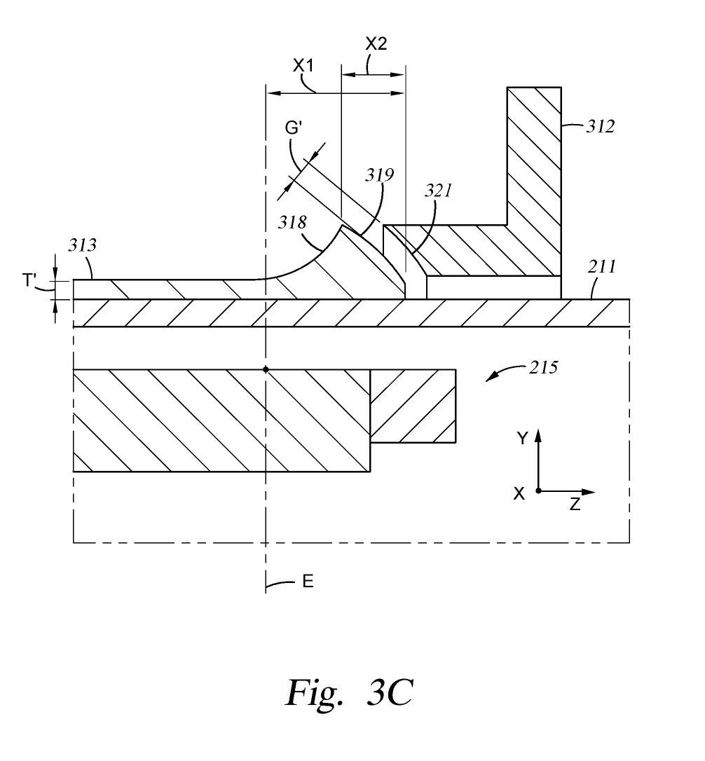

FIG. 3A shows an end of a cylindrical target assembly 310 that may be used in place of the cylindrical target assembly 110, according to one embodiment of the disclosure. The cylindrical target assembly 310 includes the backing tube 211 having a cylindrical target 313 disposed thereon which are rotatably disposed about magnet array assembly 215. The cylindrical target 313 comprises a single body or a plurality of cylindrical target segments and in some embodiments, is adhered to backing tube 211 by a bonding layer not shown. The cylindrical target assembly 310 further includes a dark space shield 312 disposed around the backing tube 211, where the dark space shield 312 is spaced apart, and electrically isolated, from both the cylindrical target 313 and the backing tube 211. In some embodiments, the dark space shield 312 is formed from a conductive material, such as stainless steel, and is typically coupled to an earthen ground (not shown). The backing tube 211 and thus the cylindrical target 313 rotate about the Z-axis while the magnet array assembly 215 remains stationary. The cylindrical target 313 comprises a target material, having a thickness T. In some embodiments, the cylindrical target 313 comprises a target material selected from the group consisting of a metal or a dielectric material, such as aluminum, molybdenum, titanium, copper, or the like, silicon, IZO, IGZO, AZO, SnO, AlSnO, InGaSnO, ceramics, and other materials, such as materials used to form a transparent conductive oxide. The thickness T is between about 5 mm and about 30 mm, such as between 9 mm and about 26 mm, such as between 9 mm and about 15 mm for a target material comprising a dielectric material and between about 16 mm and 26 mm for a target material comprising a metal.

FIG. 3B is a close up view of a portion of the end of the cylindrical target assembly 310, as shown in FIG. 3A. Herein, the cylindrical target 313 includes an inner surface 313B having an inner diameter, an outer surface 313A coaxially disposed about the inner surface 313B and having an outer diameter, and one or more target ends wherein each target end is shaped to form a contoured surface 319 which extends from the inner surface 313B to the outer surface 313A. Herein, the outer surface 313A and the contoured surface 319 do not extend outside of the arc of the equal magnetic line M. The shape of the contoured surface 319 ensures that sputtering energy along substantially all surfaces of the cylindrical target 313 is sufficient to prevent redeposition material, such as the layers of redeposition material 214 shown in prior art FIGS. 2A-2D, from accumulating on cylindrical target 313, including the contoured surface 319. This is because the magnetic field found at the surfaces that are at or inside of equal magnetic line M is sufficiently strong enough to ensure that the target surface is continually and sufficiently bombarded with ionized gas atoms so that layers of redeposited material do not accumulate thereon. In this embodiment, the contoured surface 319 is in the shape of an arc where the arc has a center C, which is located at the uniform magnetic field edge E and the surface of the center end magnet 217, and has an arc radius R′ that is about equal to or less than the radius R of the equal magnetic line M, such as an arc radius R′ that is about 5 mm less than the radius R, such as about 3 mm less than the radius R, such as about 1 mm less than the radius R. Herein, arc radius R′ is between about 10 mm and about 100 mm, such as between about 10 mm and about 50 mm, such as between about 20 mm and about 40 mm, such as between about 25 mm and about 35 mm, such as about 30 mm. In other embodiments, the contoured surface 319 is defined by an arc having the arc radius R′ wherein the arc intersects the outer surface 313A at a distance from the end of the cylindrical target 313 that is about equal to or greater than the second distance X2, such as between about 5 mm and about 30 mm when measured parallel to the longitudinal axis Z of the cylindrical target 313, such as between about 5 mm and about 25 mm, for example between about 5 mm and about 12 mm for a target material comprising a dielectric material and between about 8 mm and about 20 mm for a target material comprising a metal.

FIGS. 3A and 3B further disclose a dark space shield 312 having a contoured portion 321 of the same general shape as the contoured surface 319. The contoured portion 321 of dark space shield 312 provides a gap G′ that has a substantially uniform distance between the contoured surface 319 and the dark space shield 312 to prevent plasma from forming in that region. Herein, the gap G′ is between about 1 mm and about 5 mm, such as between about 2 mm and 4 mm, such as about 3 mm. The contoured portion 321 of dark space shield 312 comprises an arc having center C and a radius of R′ plus G′.

FIG. 3C show an erosion profile of a used surface of the cylindrical target 313. Typically, the surface of the cylindrical target 313 erodes at a uniform rate between the uniform magnetic field edge E and a second uniform magnetic field edge at an opposing end of the cylindrical target assembly 310. This uniform erosion between uniform magnetic field edges results in a used thickness T′ along the majority of the surface of the cylindrical target 313. End profile 318 shows a typical non-uniform erosion profile between the uniform magnetic field edge E and equal magnetic line M. Herein, the contoured surface 319 is protected from erosion by dark space shield 312 and maintains its shape during the useful lifetime of the cylindrical target 313.

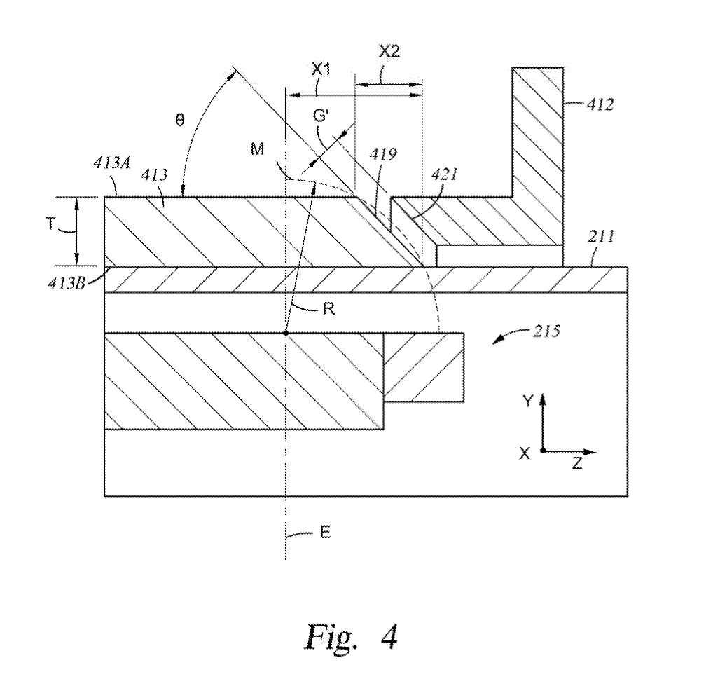

FIG. 4 is a close up view of a cylindrical target assembly 410 used in the process chamber 100 as the cylindrical target assembly 110, according to another embodiment of the disclosure. In this embodiment, a contoured surface 419 of a target end extends from an outer surface 413A of an outer diameter of the cylindrical target 413 to an inner surface 413B of an inner diameter of the cylindrical target 413. As shown in FIG. 4, the contoured surface 419 is chamfered such that the outer surface 413A and the contoured surface 419 are at or inside of the equal magnetic line M. Herein, the contoured surface 419 joins the outer surface 413A at a distance from the end of the cylindrical target 413, when measured parallel to a longitudinal axis Z of the cylindrical target, that is about equal to or greater than the second distance X2, such as between about 5 mm and about 30 mm, such as between about 5 mm and about 25 mm, for example between about 5 mm and about 12 mm for a target material comprising a dielectric material and between about 8 mm and about 20 mm for a target material comprising a metal. The contoured surface 419 of the target end has a slope of angle θ, where angle θ is between about 30° and about 60° from the longitudinal axis Z of the cylindrical target 413, such as about 45°.

FIG. 4 further discloses a dark space shield 412 spaced apart from contoured surface 419 by gap G′, where G′ is between about 1 mm and about 5 mm, such as between about 2 mm and 4 mm, such as about 3 mm. Herein, the dark space shield has an angled portion 421 that is substantially parallel to the chamfer of contoured surface 419.

Embodiments described herein provide for rotatable cylindrical targets and cylindrical target assemblies that substantially reduce or eliminate the accumulation of redeposited material on the cylindrical target surface.

While the foregoing is directed to embodiments of the present disclosure, other and further embodiments of the disclosure may be devised without departing from the basic scope thereof, and the scope thereof is determined by the claims that follow.

1. A cylindrical target assembly, comprising:
a backing tube; and
a cylindrical target disposed around the backing tube, the cylindrical target comprising:
an inner surface;
an outer surface coaxially disposed about the inner surface; and
one or more contoured surfaces each extending from the inner surface to the outer surface at a respective target end.

2. The cylindrical target assembly of claim 1, wherein the cylindrical target comprises a target material selected from the group consisting of a metal, an oxide, a carbide, a nitride, and combinations thereof.

3. The cylindrical target assembly of claim 1, wherein the cylindrical target comprises a plurality of target segments.

4. The cylindrical target assembly of claim 1, wherein at least one of the one or more contoured surfaces comprise an arc.

5. The cylindrical target assembly of claim 1, wherein at least one of the one or more contoured surfaces comprises a chamfer having an angle of between about 30° and about 60° with respect to the longitudinal axis of the cylindrical target.

6. The cylindrical target assembly of claim 1, further comprising one or more shields disposed about, and spaced apart from, the backing tube.

7. The cylindrical target of claim 1, wherein each of the one or more contoured surfaces comprise an arc, and wherein the center of the arc is located at an edge of a uniform magnetic field and a surface of a stationary magnet array to be disposed within the backing tube.

8. The cylindrical target assembly of claim 2, wherein the target material has a thickness between about 5 mm and about 30 mm.

9. The cylindrical target assembly of claim 4, wherein each of the one or more arcs joins the outer surface between about 5 mm and about 30 mm from the respective end of the cylindrical target when measured parallel to the longitudinal axis thereof.

10. The cylindrical target assembly of claim 5, wherein the chamfer joins the outer surface between about 5 mm and about 30 mm from the respective end of the cylindrical target when measured parallel to the longitudinal axis thereof.

11. The cylindrical target assembly of claim 6, wherein each of the one or more shields and a respective contoured surface define a gap, and wherein the gap is between about 1 mm and about 5 mm.

12. The cylindrical target assembly of claim 7, further comprising the stationary magnet array.

13. The cylindrical target of claim 9, wherein the radius of each of the one or more arcs is between about 10 mm and about 40 mm.

14. A cylindrical target assembly, comprising:
a backing tube;
a cylindrical target disposed around the backing tube, the cylindrical target comprising:
an inner surface;
an outer surface coaxially disposed about the inner surface; and
one or more contoured surfaces each extending from the inner surface to the outer surface at a respective target end; and
one or more shields disposed about, and spaced apart from, the backing tube.

15. The cylindrical target assembly of claim 14, further comprising a stationary magnet array disposed within the backing tube.

16. The cylindrical target assembly of claim 14, wherein each of the one or more shields and a respective contoured surface define a gap of between about 1 mm and about 5 mm.

17. The cylindrical target assembly of claim 14, wherein at least one of the contoured surfaces comprises a chamfer having an angle between about 30° and about 60° with respect to the longitudinal axis of the cylindrical target.

18. The cylindrical target assembly of claim 17, wherein the chamfer begins between about 5 mm and about 30 mm from an end of the cylindrical target when measured parallel to the longitudinal axis thereof.

19. A cylindrical target assembly comprising:
a backing tube; and
a cylindrical target disposed around the backing tube, the cylindrical target comprising an inner surface having an inner diameter, an outer surface having an outer diameter, and a contoured surface connecting the inner surface and the outer surface at an end of the cylindrical target, wherein the contoured surface intersects the outer surface between about 5 mm and about 20 mm from the end of the cylindrical target when measured parallel to the longitudinal axis thereof.

20. The cylindrical target assembly of claim 19, wherein the contoured surface comprises a chamfer having an angle between about 30° and about 60° with respect to the longitudinal axis of the cylindrical target.
